(19) United States
(12) Patent Application Publication
(10) Pub. No.: US 2006/0157851 A1
(43) Pub. Date: Jul. 20, 2006

(54) Semiconductor device and method for manufacturing the same

(76) Inventor: Hiroyuki Kawashima, Kanagawa (JP)

Correspondence Address: David R. Metzger;SONNENSCHEIN NATH & ROSENTHAL, Sears Tower, Wacker Drive Station, P.O. Box 061080, Chicago, IL, 60606-1080, US

(21) Appl. No.: 11/287,136

(22) Filed: Nov. 22, 2005

(30) Foreign Application Priority Data
Dec. 7, 2004 (JP) P2004-353533

(51) Int. Cl. H01L 21/311; H01L 23/48

(52) U.S. Cl. 257/750; 438/700

(57) ABSTRACT

A semiconductor device includes a first insulating film, a second insulating film and a third insulating film that are stacked in this order, and a first wiring formed in a first wiring trench formed in the stacked insulating films. The first insulating film is made of a film whose dielectric constant is lowest among the stacked insulating films, the third insulating film serves as a polishing stopper, and the second insulating film serves as an etching stopper. Manufacturing methods are also described.

### CROSS REFERENCES TO RELATED APPLICATIONS

The present invention contains subject matter related to Japanese Patent Application JP 2004-353533 filed in the Japanese Patent Office on Dec. 7, 2004, the entire contents of which being incorporated herein by reference.

### BACKGROUND OF THE INVENTION

This invention relates to a semiconductor device and a method for manufacturing the same wherein a multi-layered wiring structure of high performance can be easily formed.

A recent tendency toward microfabrication and a high degree of integration of semiconductor devices presents a serious problem in an electric signal delay ascribed to the time constant of wirings. To avoid this, low electric resistance copper (Cu) wirings have been put in place for a conductive layer used in a multi-layered wiring structure instead of an aluminium (Al) alloy.

Unlike metal materials such as aluminium used in conventional multi-layered structures, copper is so difficult in patterning through dry etching that a so-called damascene process, in which a wiring trench is formed in an insulating film and copper is buried in the wiring trench to form a wiring pattern, has generally been applied to the formation of a multi-layered wiring structure of copper. Especially, attention has now been paid to a so-called dual damascene process wherein a connection hole and a wiring trench are formed and are, respectively, buried with copper at the same time. Thus, this method is effective in reducing the number of steps (see, for example, Japanese Patent Laid-open No. Hei 11-45887).

With highly integrated semiconductor devices, an increase of wiring capacity leads to a lowering of working speed of the semiconductor device. Hence, it is essential to use a film of low dielectric constant as an interlayer insulating film to provide fine multi-layered wirings for the purpose of suppressing the wiring capacitance from increasing.

The materials for the low dielectric constant film include, aside from fluorine-containing silicon oxide (FSG) which has shown relatively good results as hitherto employed and has a dielectric constant of about 3.5, organosilicon compounds, typical of which are polyaryl ethers (PAE), inorganic materials, typical of which are hydrogensilsesquioxane (HSQ) and methylsilsesquioxane (MSQ), and the like materials capable of providing a low dielectric constant film whose dielectric constant is as low as about 2.7. Moreover, attempts have been made so that such materials as mentioned above are rendered porous for application as a low dielectric constant material having a specific constant of about 2.2.

Where the dual damascene process is applied to an interlayer insulating film of low dielectric constant, it is necessary to solve the following technical constrain problems.

Firstly, since a low dielectric constant film composition is similar to a composition of a resist used for patterning, with an attendant problem that the low dielectric constant film is liable to suffer damage in the course of a resist removing process. More particularly, when a resist peeling treatment is effected after etching with use of a resist mask or when resist regeneration is effected if a processed resist pattern does not satisfy a production specification, it is essential to suppress damage against a low dielectric constant film.

Secondly, application to a borderless structure wherein no registration allowance exists between a wiring and a connection hole is necessary. As a semiconductor device is more microfabricated, formation of multi-layered wirings of 0.18 μm and onward generations is based on the premise that a working process responsible for a borderless structure is adopted. Accordingly, where wiring trenches and connection holes are simultaneously formed in the interlayer insulting films containing a low dielectric constant film according to the dual damascene process, the use of a process, in which a variation of via resistance ascribed to the deviation of registration is small, is important.

Thirdly, for the formation of a wiring trench in good controllability of depth, it is desirable to provide an etching stopper film near the bottom of the wiring trench. Nevertheless, if an etching stopper film is interposed within interlayer insulating films, an increase of interlayer capacitance results. Thus, a dual damascene process for making a low dielectric constant interlayer structure is required wherein while a wiring trench is controlled, the increase in capacitance can be suppressed.

A dual damascene process capable of solving such technical restrictions has been proposed (e.g. see Japanese Laid-open Patent Application No. 2004-63859). In this connection, however, when such a conventional dual damascene process as mentioned above is applied to finer multi-layered wirings of the 5 nm generation and onward, the following problems arise.

First, a first mask forming layer is formed of a silicon oxide film, so that the first mask forming layer left as a cap layer for wiring becomes high in specific inductive capacity. If the a silicon oxide film having a specific inductive capacity of about 4 is left as a cap layer for wiring, an apparent dielectric constant between wirings is unlikely to lower even when the specific inductive capacity of an organic insulating film formed as an insulating film between the wirings is lowered.

Second, if a first mask forming layer is changed from a silicon oxide film to a methylsilsesquioxane film (SiOC) in the conventional dual damascene process set out above in order to lower the specific inductive capacity of the cap layer of wirings, a disadvantage is involved in that when a silicon carbide (SiC) film at a bottom of a connection hole is opened, a high etching selection ratio between the methylsilsesquioxane film serving as a cap layer of a lower wiring and the silicon carbide film is not attained, thereby causing the organic film at the bottom of the connection hole in a borderless pattern to be exposed. In this condition, when the organic film of an upper wiring layer is etched, the organic film of a lower wiring layer is etched as well, thereby enabling metallic wirings to be failure in connection or reliability.

Third, when a copper film is buried in a wiring trench and additional copper is removed according to chemical mechanical polishing (which may be hereinafter referred to as CMP), remaining cap films varies owing to the difference in wiring density, the variation in wafer inplane and the variation in intrawafer. In order not to expose an organic film at the bottom of the connection hole of the borderless pattern in case where the cap remaining film is minimized in number in a pattern wherein a copper wiring density is high and dishing is liable to occur, it is necessary to form a cap remaining film preset as thicker, resulting in an increase of interwiring capacitance.

### SUMMARY OF THE INVENTION

The problems to solve include a difficulty in suppressing a rise of specific inductive capacity caused by a so-called cap film that serves to protect a low dielectric constant film from polishing or etching and a difficulty in application to a borderless structure that has little registration allowance between a wiring and a connection hole. These problems are solved according to the following embodiments of the invention.

The semiconductor device of the invention includes a first insulating film, a second insulating film and a third insulating film that are successively stacked, and a wiring formed in a wiring trench formed in the stacked insulating films. The most prominent feature resides in that the first insulating film is one that is lowest in dielectric constant among the stacked films, the third insulating film serves as a polishing stopper, and the second insulating film serves as an etching stopper.

A first method for manufacturing a semiconductor device according to the invention includes successively stacking a first insulating film, a second insulating film and a third insulating film, and forming a wiring in a wiring trench formed in the stacked insulating films, wherein the most prominent feature resides in that the first insulating film is formed of a film that is lowest in dielectric constant among the stacked insulating films, the third insulating film serves as a polishing stopper on formation of the wiring, and the second insulating film serves as an etching stopper on formation of a connection hole communicated to the wiring.

A second method for manufacturing a semiconductor device having interlayer insulating films including an organic insulating film according to the invention includes the steps of:

successively forming, on a substrate, a first insulating film serving as an insulating film that allows a connection hole to pass therethrough and made of a SiOC material, and a second insulating film serving as an insulating film in which a wiring layer is formed and which is made of an organic insulating film;

successively forming, on the second insulating film, a first mask forming layer made of a SiOC material, a second mask forming layer made of a SiC material that is different in type from that of the first mask forming film, a third mask forming layer made of a SiO₂ material that is different in type from that of the second mask forming layer, a fourth mask forming layer made of a SiN material that is different in type from that of the third mask forming layer, and a fifth mask forming layer made of a SiO₂ material that is different in type from that of the fourth mask forming layer;

forming a fifth mask by patterning the fifth mask forming layer to form a wiring trench pattern;

forming a resist mask having a connection hole pattern over the fourth mask forming layer including the fifth mask;

subjecting from the fifth mask forming layer to the first mask forming layer and also the second insulating film to etching through the resist mask used as an etching mask to make a connection hole;

etching the fourth mask forming layer through an etching mask of the fifth mask to form a fourth mask having a wiring trench pattern and etching the first insulating film to part thereof to form the connection hole as extended;

subjecting from the third mask forming layer to the first mask forming layer to etching through the fourth mask used as an etching mask to form a third mask, a second mask, and a first mask, each having a wiring trench pattern therein, and etching the first insulating film left at a bottom of the connection hole to make a connection hole arriving at the substrate;

etching the second insulating film through the third mask used as an etching mask to form a wiring trench in the second insulating film; and

removing the third mask left after the formation of the wiring trench.

The effects and advantages of the semiconductor device and the manufacturing method set out hereinabove are described below.

The semiconductor device of the invention is advantageous in that since the first insulating film is formed of a film whose dielectric constant is lowest among the stacked insulating films, the wiring formed in the first insulating film can be reduced with respect to interwiring capacitance, thereby providing a wiring structure of high performance. Moreover, the third insulating film is provided as a polishing stopper upon formation of wirings. Accordingly, where wirings are formed such that a metal or the like is buried or embedded in a wiring trench and an additional wiring material is removed by polishing, the first insulating film whose dielectric constant is lowest among the stacked insulating films has no possibility of being scraped. Thus, the effect of reducing the interwiring capacitance ascribed to the first insulating film is not impaired. Additionally, the second insulating film serves as an etching stopper when a connection hole communicated to a wiring is formed. Thus, if a connection hole is formed as extended from wirings in case where a connection hole of a borderless structure is formed or where a deviation of registration is caused to occur in patterning of connection holes, etching for the formation of the connection hole is stopped by means of the second insulating film. In this way, a slit-shaped, deep trench is not formed at a side portion of the wiring. As a result, a wiring structure of high reliability is obtained.

In the first manufacturing method of the invention, the first insulting film is formed of a film that is lowest among the stacked insulating films, so that the wiring formed in the first insulating film can be reduced with respect to the interwiring capacitance. This is advantageous in that a wiring structure of high performance can be obtained. Moreover, the third insulating film is used as a polishing stopper in the course of the formation of wiring, for which in case where a wiring material, such as a metal or the like, is embedded in a wiring trench and an additional wiring material is removed by polishing, the additional wiring material can be removed without removal of the fist insulating film that is lowest in dielectric constant among the stacked insulating films. Thus, the reducing effect of the interwiring capacitance of the first insulating film is not impaired. In addition, the second insulating film serving as an etching stopper is not formed as being thin during the course of polishing, and can keep function as an etching stopper. The second insulating film acts as an etching stopper in forming a connection hole communicated to wiring. Thus, if a connection hole is formed as extended or running over from wirings in case where a connection hole of a borderless structure is formed or where a deviation of registration is caused to occur in patterning of connection holes, etching for the formation of the connection hole is stopped by means of the second insulating film. In this way, a slit-shaped, deep trench is not formed at a side portion of the wiring. As a result, a wiring structure of high reliability is obtained.

Further, when compared with a manufacturing method where a film of high polishing selection ratio is not inserted, a total film thickness of the second and third insulating films formed on the first insulating film can be made small. Accordingly, if a wiring height is made constant, a ratio of an organic film having a low dielectric constant can be increased, thereby enabling the interwiring capacitance to be low. Because the variation in thickness of the second and third insulating films formed on the first insulating film can be made small, resulting in a small variation in wiring height. This eventually leads to a small variation in wiring resistance and interwiring capacitance. Moreover, the third insulating film acts as a stopper layer upon polishing, a polishing allowance can be lessened. This results in a small processing depth of the insulating film, with the attendant advantage in ease of processing. Thus, a semiconductor device having a multi-layered wiring structure of high performance can be manufactured in high yield.

In the second manufacturing method of the invention, an etching mask made of three or more insulating films by use of at least two types of materials is arranged on the second insulating film made of an organic insulating material and provided between wirings, so that a variation in thickness of the insulating films formed on the second insulating film can be suppressed to minimum. The third mask acts as a stopper in the course of polishing for an additional wiring material after embedding a wiring material in a wiring trench. Thus, the first and second masks formed on the second insulating film are not formed as being thin in the vicinity of a pattern where the wiring material is liable to cause dishing. In this way, if a deviation of registration between connections holes and a lower wiring layer occurs in any pattern, an insulating film formed on an organic insulating film, in which the lower wiring layer is formed, does not have a thickness that is smaller than a desired thickness. As a result, a connection hole can be prevented from passing through the organic film at side walls of the lower wiring layer. Accordingly, when compared with a manufacturing method wherein a film of high polishing selection ratio is not inserted, the total thickness of the insulating films formed on the second insulating film can be made small. If a wiring height is made constant, the thickness of the second insulating film made of an organic insulating film of low dielectric constant can be increased, thus ensuring a low interwiring capacitance. Moreover, a variation in thickness of the insulating film formed on the second insulating film acts as a stopper layer in the course of polishing, a polishing allowance necessary for planarization of wiring can be lessened. Consequently, a processing depth in the insulating film becomes small, with an attendant advantage in ease of processing. Additionally, the fifth mask to the third mask are removed, so that a wiring aspect in forming wiring trenches and connection holes prior to embedding of wirings becomes small, ensuring ease in embedding a wiring material. Accordingly, a semiconductor device having a multi-layered wiring structure of high performance can be manufactured in high yield.

A desire of manufacturing a semiconductor device having a multi-layered structure of high performance has been realized by forming a plurality of insulating films in which wirings are formed and by permitting the respective insulating films to have functions as a low dielectric constant, a polishing stopper and an etching stopper. More particularly, the object is achieved according to the method of manufacturing a semiconductor device, in which a first insulating film, a second insulating film and a third insulating film, each serving as an interlayer insulating film for wiring layer, are stacked, and a wiring is formed in a wiring trench formed in the stacked insulating films, wherein the first insulating film is formed of a film that has the lowest dielectric constant among the stacked insulating films, the third insulating film is used as a polishing stopper, and the second insulating film is used as an etching stopper.

### BRIEF DESCRIPTION OF THE DRAWINGS

FIG. 1 is a schematic section view of a semiconductor device according to one embodiment of the invention;

FIGS. 2A to 2D are, respectively, an illustrative view showing the step of manufacturing a semiconductor device according to one embodiment of the invention;

FIGS. 3A to 3C are, respectively, an illustrative view showing the step of a manufacturing a semiconductor device according to another embodiment of the invention;

FIGS. 4A to 4C are, respectively, an illustrative view showing a step similar to the forgoing figures and subsequent to the steps of FIGS. 3A to 3C;

FIGS. 5A to 5C are, respectively, an illustrative view showing a step subsequent to the steps of FIGS. 4A to 4C; and

FIGS. 6A to 6C are, respectively, an illustrative view showing a step subsequent to the steps of FIGS. 5A to 5C.

### DETAILED DESCRIPTION OF THE PREFERRED EMBODIMENTS

### Embodiment 1

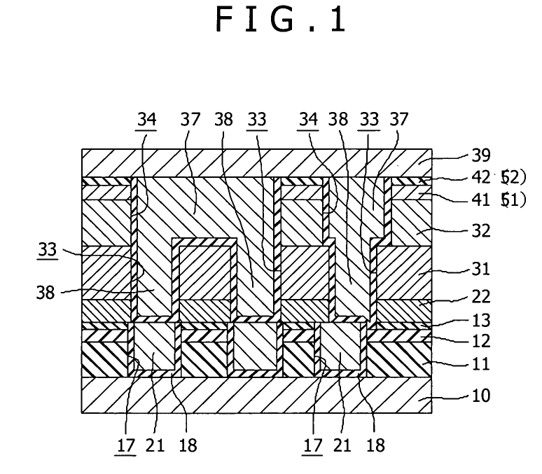

A semiconductor device according to an embodiment of the invention is illustrated with reference to FIG. 1.

As shown in FIG. 1, a substrate 10 has a first insulating film 11 formed thereon as an insulating film in which a wiring layer is to be formed. The first insulating film 11 is formed, for example, of an organic insulating film having a low dielectric constant. The organic insulating film used as the first insulating film includes, for example, a polyaryl ether (PAE) film. Alternatively, a porous film of an organic insulating material may also be used. Aside from the PAE film, a benzocyclobutene (BCB) film, a polyimide film, an amorphous carbon film and the like may be likewise used.

A second insulating film 12 is formed on the first insulating film 11. The second insulating film 12 is formed of an insulating film that serves as an etching stopper when a subsequently formed, third insulating film 13 is etched and is constituted, for example, of an insulating film based on silicon carbide oxide (SiOC). Alternatively, the second insulating film 12 may be formed, for example, of a porous insulating film based on silicon carbide oxide or may be formed of a SiOC film having a low specific inductive capacity.

Furthermore, a third insulating film 13 is formed on the second insulating film 12. The third insulating film 13 functions as a polishing stopper when an additional portion of a wiring material embedded in a subsequently formed wiring trench is polished, and is formed, for example, of a silicon carbide (SiC) insulating film. The film thickness ranges from 3 nm to 20 nm. If the thickness of the third insulating film 13 is smaller than 3 nm, its function as a polishing stopper is not expected. On the contrary, when the thickness is larger than 20 nm, an undesirable increase in dielectric constant is brought about in such a way that an effect of using an organic insulating film of low dielectric constant as the first insulating film 11 is negated. For this reason, the third insulating film 13 should preferably be formed within such a thickness range as defined above. More preferably, the thickness ranges from 5 nm to 10 nm.

For instance, the first to third insulating films 11 to 13 are so formed as having thicknesses of 80 nm, 30 nm and 10 nm in the order from the first insulating films 11. The first insulating film 11 to the third insulating film 13 are preferably formed of light transmitting materials. The formation with light transmitting materials allows easy optical alignment at the time of mask registration. In this way, stacked insulating films including from the first insulating film 11 to the third insulating film 13 are formed. A given amount of an atom such as nitrogen, hydrogen, oxygen or the like may be contained in SiC used as the film material.

The third insulating film 13, second insulating film 12 and first insulating film 11 are formed with a first wiring trench 17 therein. A first wiring 21 is formed inside the first wiring trench 17 through a barrier layer 18. The barrier layer is formed, for example, a tantalum (Ta) film generally called “barrier metal”. The first wiring 21 is formed, for example, of copper or a copper alloy.

A barrier film 22 is formed on the third insulating film 13 so as to cover the first wiring 21 for the purposes of protection against oxidation and inhibition of copper diffusion. This barrier film is formed, for example, of a 30 nm thick silicon carbide (SiC) film. Moreover, a first interlayer insulating film 31, through which a connection hole 33 is passed, is formed on the barrier film 22. The first interlayer insulating film 31 may be formed, for example, of a 100 nm thick carbon-containing silicon oxide (SiOC) film. It will be noted that the first interlayer insulating film 31 is a first insulating film in which a connection hole is formed. In order to discriminate from the first insulating film 11, this insulating film is defined as the first interlayer insulating film 31.

A second interlayer insulating film 32, in which a second wiring 37 is formed, is formed on the first interlayer insulating film 31. The second interlayer insulating film 32 is formed by forming an organic insulating film having a specific inductive capacity of about 2.4 in a thickness of 80 nm. For the organic insulating film used as the second interlayer insulating film 32, a polyaryl ether (PAE) film may be used, for example. The organic insulating film can be formed by a procedure wherein a precursor is deposited according to a spin coating process, followed by thermal curing at 350° C. to 450° C. As a matter of course, the precursor may be so prepared as to provide a porous film. Aside from the PAE film, there may be used a enzocyclobutene (BCB) film, a polyimide film and an amorphous carbon film. It will be noted that the second interlayer insulating film is a second insulating film wherein a wiring is formed and is indicated as the second interlayer insulating film 32 in order to discriminate it from the first-mentioned second insulating film 12.

Further, a first mask forming layer 41 (first mask 51) and a second mask forming layer 42 (second mask 52) are, respectively, formed on the second interlayer insulating film 32 in the order from the lower layer. The first mask forming layer 41 is formed, for example, of a 30 nm thick SiOC film, and the second mask forming layer 42 is formed, for example, of a 10 nm thick SiC film. Especially, the second mask forming layer 42 functions as a polishing stopper when an additional portion of a wiring material to be buried or embedded in a subsequently formed wiring trench is polished. The layer 42 is formed, for example, of a silicon carbide (SiC) insulating film with its thickness ranging from 3 nm to 20 nm. If the thickness of the second mask forming layer 42 is smaller than 3 nm, function as the polishing stopper is not expected. On the contrary, when the thickness is large than 20 nm, an undesirable rise of dielectric constant that negates the effect of using an organic insulating film of low dielectric constant as the second interlayer insulating film 32 is brought about. For this reason, the second mask forming layer 42 should preferably be formed within such a thickness range as indicated above and more preferably within a range of from 5 nm to 10 nm.

The first interlayer insulating film 31, second interlayer insulating film 32, first mask forming layer 41 and second mask forming layer 42 are preferably formed of light transmitting materials, respectively. The formation with such a light transmitting material enables one to permit easy optical alignment upon mask registration.

A second wiring trench is formed in the second mask forming layer 42, first mask forming layer 41 and second interlayer insulating film 32, and a connection hole 33 communicating from the bottom of the second wiring trench 34 to the first wiring 21 is formed in the first interlayer insulating film 31.

The second wiring trench 34 and the connection hole 33 are, respectively, buried therein with a wiring material through the barrier layer 35. A second wiring 37 made of a wiring material is formed inside the second wiring trench 34 through the barrier layer 35. A plug 38 made of a wiring material is formed inside the connection hole 33 connecting to the bottom of the second wiring 37 through the barrier layer 35. In a manner as set out hereinabove, a multi-layered wiring structure of a so-called dual damascene structure is formed.

The semiconductor device having such a multi-layered structure as set forth above is advantageous in that since the first insulating film 11 is formed of a film that has the lowest dielectric constant among from the first insulating film to the third insulating film 13, the first wiring 21 formed in the first insulating film 11 can be reduced in interwiring capacitance, so that a wiring structure of high performance can be obtained. The third insulating film 13 serves as a polishing stopper when the first wiring 21 is formed, for which where an additional wiring material after burying a metal or the like in the first wiring trench 17 to provide the first wiring 21 is removed by polishing, the first insulating film 11 having the lowest dielectric constant among the stacked insulating films is not polished off. Thus, the effect of reducing the interwiring capacitance ascribed to the first insulating film 11 is not impaired. Where a connection hole of a borderless structure is, for example, formed, or where registration deviation takes place at the time of patterning of the connection hole 33 under which the connection hole 33 is formed as extended from the first wiring 21, etching for forming the connection hole 33 is stopped by means of the second insulating film 12 and thus, no slit-shaped, deep trench is formed at sides of the first wiring 21. This leads to a wiring structure of high reliability.

Likewise, the second interlayer insulating film 32 at which the second wiring 37 is formed is formed of a film that has the lowest dielectric constant among from the second interlayer insulating film 32 to the second mask forming layer 42 stacked one on another, so that the second wiring 37 formed in the second interlayer insulating film 32 can be reduced in interwiring capacitance, with the advantage in that a wiring structure of high performance can be obtained. Moreover, since the second mask forming layer 42 serves as a polishing stopper upon formation of the second wiring 37, for which where the second wiring 37 is formed by burying a metal or the like in the second wiring trench 34 and an additional wiring material is removed by polishing, the second interlayer insulating film 32 that has the lowest dielectric constant among from the second interlayer insulating film 32 to the second mask forming layer 42 is not polished off. Thus, the effect of reducing the interwiring capacitance ascribed to the second interlayer insulating film 32 is not impaired. The first mask forming layer 41 serves as an etching stopper when forming a connection hole (not shown) communicated to the second wiring 37. Accordingly, in case of forming a connection hole of a borderless structure or in case of registration deviation occurring upon patterning of a connection hole, for example, if the connection hole is formed as extended from the second wiring 37, etching for the formation of the connection hole is stopped by means f the first mask forming layer 41. Thus, no slit-shaped, deep trench is formed at the side of the second wiring 37. As a result, a wiring structure where the second wiring 37 is formed is one that is highly reliable.

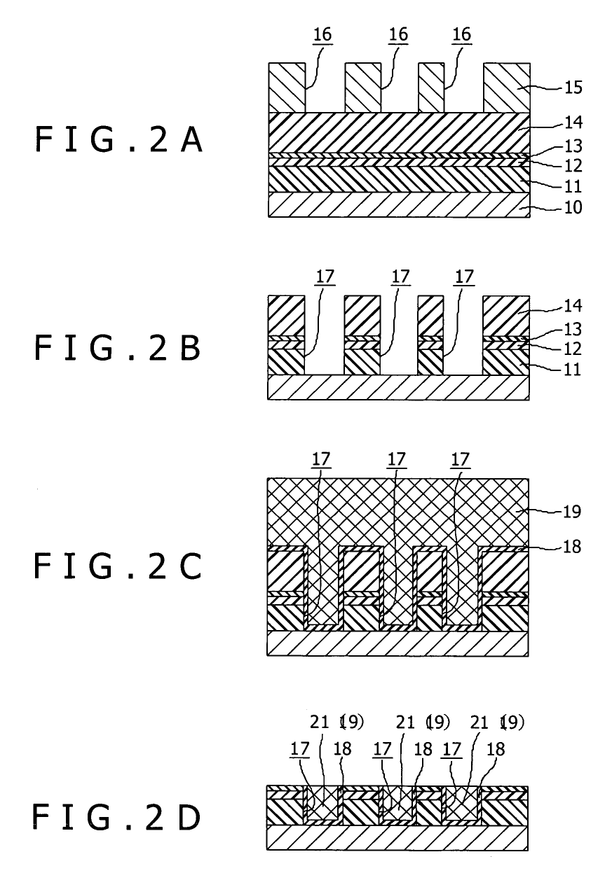

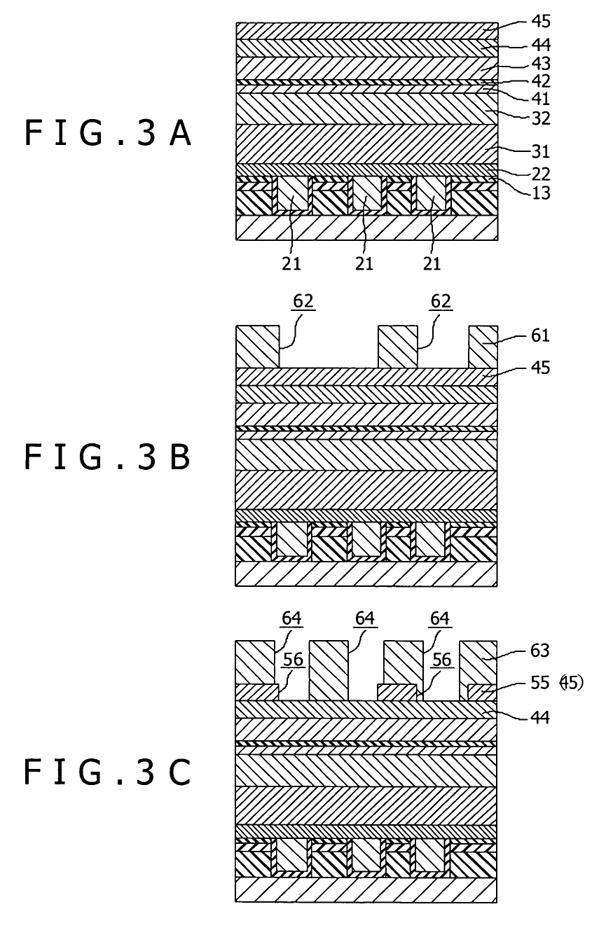

The manufacturing method of a semiconductor device according to embodiments of the invention is illustrated with reference to FIG. 2A to FIG. 6C. It will be noted that a first manufacturing method is shown mainly in FIGS. 2A to 2D, and a second manufacturing method is shown mainly in FIGS. 3A to 6C. It will also be noted that the types of film materials, thicknesses, film-forming procedures and sizes specifically indicated in these embodiments are illustrated by way of examples in order to facilitate better understanding of the invention and should not be construed as limiting the invention thereto. Moreover, the procedures of forming and processing individual films should not be construed as limitation, and may be replaced by film-forming and processing procedures for similar types of films set out in different steps.

As shown in FIG. 2A, a first insulating film 11 is formed on a substrate 10 as an insulating film in which a wiring layer is formed. The first insulating film 11 is formed, for example, of an organic insulating film having a low dielectric constant.

Subsequently, a second insulating film 12 is formed on the first insulating film 11. This second insulating film 12 is formed of an insulating film serving as an etching stopper when a subsequently formed, third insulating film 13 is etched and is formed, for example, of a silicon carbide oxide (SiOC) insulating film.

Thereafter, a third insulating film 13 is formed on the second insulating film 12. The third insulating film 13 functions as a polishing stopper when an additional portion of a wiring material buried in a wiring trench formed later is polished and is formed, for example, of a silicon carbide (SiC) insulating film. The thickness of the film 13 ranges from 3 nm to 20 nm. If the thickness of the third insulating film 13 is smaller than 3 nm, function as a polishing stopper is not expected. On the contrary, when the thickness exceeds 20 nm, an undesirable rise of dielectric constant, which may negate the effect of using an organic insulating film of low dielectric constant as the first insulating film 11, is brought about. For this reason, the third insulating film 13 is formed in such a thickness range as defined above and more preferably within a range of from 5 nm to 10 nm.

Thereafter, a fourth insulating film 14 is formed on the third insulating film 13. This fourth insulating film 14 is formed, for example, of a silicon oxide (SiO₂) film.

The respective thicknesses of the first to fourth insulating films 11 to 14 are, for instance, 80 nm, 30 nm, 10 nm and 100 nm in the order from the first insulating film 11. The first to fourth insulating films 11 to 14 are, respectively, formed of a light transmitting material. The formation with a light transmitting material allows easy optical alignment upon mask registration. In this way, stacked insulating films of the first insulating film 11 to the fourth insulating films 14 is formed.

Next, a resist film is formed on the fourth insulating film 14 and a first wiring trench pattern 16 is formed in the resist film according to an ordinary lithographic technique, thereby forming a resist mask 15.

For the formation of a SiOC film used as the second insulating film 12, a parallel plate plasma CVD device is used, for example, wherein methylsilane is used as a gas for silicon source. Film forming conditions are set at a substrate temperature of 300° C. to 400° C., a plasma power of 100 W to 800 W and a pressure of a film-forming atmosphere of about 100 Pa to 1350 Pa. If film-forming condition are so controlled as to provide a porous film, a SiOC film of low specific inductive capacity can be formed. Alternatively, an organosilica precursor may be applied by a spin coating process, followed by curing at 350° C. to 450° C. to obtain a film. Of course, the precursor may be so prepared as to provided a porous film. Using the above-indicated film-forming conditions, a SiOC film having a specific inductive capacity of about 2 to 3 may be formed.

The organic insulating film used as the first insulating film 11 may include, for example, a polyaryl ether (PAE) film. The organic insulating film may be formed by depositing a precursor by a spin coating process and thermally curing at 350° C. to 450° C. Of course, a precursor may be controlled in composition to provide a porous film. Aside from the PAE film, a benzocyclobutene (BCB) film, a polyimide film and an amorphous carbon film may also be used.

For the formation of a SiC film used as the third insulating film 13, an instance is such that a parallel plate plasma CVD apparatus is used wherein methylsilane is used as a gas for silicon source. Film forming conditions are set at a substrate temperature of 300° C. to 400° C., a plasma power of 150 W to 350 W and a pressure of a film-forming atmosphere of about 100 Pa to 1000 Pa. After control of the film-forming conditions, a given amount of an atom such as nitrogen, hydrogen, oxygen or the like may be contained in SiC. Using the film forming conditions mentioned above, a SiC film having a specific inductive capacity of about 3.5 to 5.0 can be formed.

The SiO₂ film used as the fourth insulating film 14 can be formed, for instance, according to a plasma CVD process using a monosilane (SiH₄) gas as a silicon source and a dinitrogen monoxide gas as an oxidizing agent.

Next, using the resist mask 15, the stacked film including from the fourth insulating film 14 to the first insulating film 11 is etched. For etching of the SiO₂ film of the fourth insulating film 14, the SiC film of the third insulating film 13 and the SiOC film of the second insulating film 12, an ordinary magnetron etching apparatus is used wherein a mixed gas of trifluoromethane (CHF₃), tetrafluoromethane (CF₄) and argon (Ar) is used with gas flow ratios of CHF₃, CF₄ and Ar of 1:3:8, and a bias power is set at 1300 W and a substrate temperature set at 200° C. Under these etching conditions, an etching selection ratio to the organic insulating film of the first insulating film 11 of about 3 is obtained, under which even if the surface of the substrate 10 is made of a silicon oxide (SiO₂) film, the first insulating film 11 is not passed through, so that the SiO₂ film of the substrate 10 is not etched.

Subsequently, an ordinary magnetron etching apparatus is used for the etching of the first insulating film 11. For instance, ammonia (NH₃) is used as an etching gas with a gas flow rate of 100 cm³/minute, and a bias power is set at 400 W and a substrate temperature set at 20° C. Under these etching conditions, even if the surface of the substrate 10 is made of a silicon oxide (SiO₂) film, an etching selection ratio to SiO₂ film of not lower than 100 is obtained. Thus, the underlying SiO₂ film suffers little degree of etching.

After etching of the fourth insulating film 14 to the first insulating film 11, the resist film 15 and a residual deposit formed during the etching treatment are completely removed, for example, by subjecting to ashing treatment based on an oxygen (O₂) plasma and chemical treatment with an organic amine. As a result, a first wiring trench 17 is formed in the fourth insulating film 14, third insulating film 13, second insulating film 12 and first insulating film 11 as is particularly shown in FIG. 2B.

Next, as shown in FIG. 2C, a barrier layer 18 is formed over the fourth insulating film 14 so as to cover the inner surfaces of the first wiring trench 17. This barrier layer 18 is generally called “barrier metal” and is formed, for example, of a tantalum (Ta) film. Additionally, a copper seed layer (not shown) is formed on the surface of the barrier layer 18. The barrier layer 18 and the copper seed layer (not shown) are formed, for example, according to a sputtering method. Thereafter, a wiring material film 19 is formed as to be embedded in the first wiring trench 17. This wiring material film 19 is formed, for example, of copper or a copper alloy. The film formation is carried out, for example, by an electroplating method or a sputtering method.

Next, the barrier layer 18 and the wiring material film 19 deposited on the fourth insulating film 14 are removed according to a chemical mechanical polishing (CMP) method and the fourth insulating film 14 is also removed. Eventually, as shown in FIG. 2D, a first wiring layer 21 made of the wiring material film 19 is formed through the barrier layer 18 inside the first wiring trench 17 formed in the first insulating film 11 to the third insulating film 13. At the time of the CMP treatment, a slurry and a polishing pressure are so controlled that the polishing selection ratio (SiO₂/SiC) between the SiO₂ film of the fourth insulating film (see FIG. 2C) and the SiC film of the third insulating film 13 is at about 10 to 100. Thus, most of the SiO₂ film is removed. If overpolishing to an extent is carried out, the SiC film is not passed through, and the stacked film consisting of the third insulating film 13 made of the SiC film and the second insulating film made of the SiOC film is left uniformly irrespective of the wiring density and the wafer inplane. In fact, it is favorable to completely remove the SiO₂ film of the fourth insulating film 14 (see FIG. 2C). In this connection, however, with a pattern having a high degree of overplating of the wiring material film 19, complete removal of the SiO₂ film may not be achieved in some case. If the SiO₂ film is left partly, no problem arises when the variations of wiring resistance and interwiring capacitance are within allowable ranges. It is to be noted that in the drawings, the fourth insulating film 14 is depicted as in a completely removed condition.

One instance of chemical mechanical polishing (CMP) conditions for the wiring material film (copper film) 19 is set out below: a stacked pad of soft and hard polyurethane materials is used as a polishing pad; an alkaline silica-based polishing solution containing an oxidizing agent and a surface active agent is provided as a polishing liquid; an amount of the polishing liquid is set at 100 ml/minute to 500 ml/minute, e.g. at 200 ml/minute; the number of revolutions of the polishing pad is set at 100 rpm, the number of revolutions of a wafer set at 110 rpm, and a polishing pressure set at 300 g/m²; and a polishing time is sufficient to attain overpolishing by 10% after removal of copper from the whole surfaces. An instance of chemical mechanical polishing (CMP) conditions for the barrier layer (tantalum film) film 18 includes those indicated below: a stacked pad of soft and hard polyurethane materials is used as a polishing pad; an alkaline silica base polishing solution containing an oxidizing agent and a surface active agent is used as a polishing liquid; an amount of the polishing liquid is set at 100 ml/minute to 500 ml/minute, e.g. at 200 ml/minute; the number of revolutions of the polishing pad is set at 100 rpm, the number of revolutions of a wafer set at 110 rpm, and a polishing pressure set at 300 g/m²; and a polishing time is set at 60 seconds.

Next, as shown in FIG. 3A, a barrier film 22 is formed on the third insulating film 13 so as to cover the first wiring 21 for the purposes of protection against oxidation and inhibition of copper diffusion. This barrier film 22 is formed, for example, of a 30 nm thick silicon carbide (SiC) film. Subsequently, a connection hole passing through the first interlayer insulating film 31 is formed. This first interlayer insulating film 31 can be formed, for example, of a carbon-containing silicon oxide (SiOC) film. It will be noted that the first interlayer insulating film 31 is a first insulating film in which a connection hole is formed and is indicated as the first interlayer insulating film 31 for discrimination from the first insulating film 11.

For the formation of the SiC film, an instance is such that a parallel plate plasma CVD apparatus is used and a methylsilane gas is used as a silicon source. The film-forming conditions are set at a substrate temperature of 300° C. to 400° C., a plasma power of 150 W to 350 W, and a pressure of a film-forming atmosphere of about 100 Pa to 1000 Pa. The film-forming conditions are so controlled as to permit SiC to be contained with a given amount of nitrogen, hydrogen or oxygen atom. Using such film-forming conditions as indicated above, a SiC film having a specific inductive capacity of about 3.5 to 5.0 can be formed.

Next, a second interlayer insulating film 32 is formed on the first interlayer insulating film 31. The second interlayer insulating film 32 is formed by forming a 80 nm thick organic insulating film having a specific inductive capacity of about 2.4. It will be noted that the second interlayer insulating film 32 is a second insulating film in which a wiring layer is formed and, for discrimination from the second insulating film 12, is indicated as the second interlayer insulating film 32.

For the organic insulating film used as the second interlayer insulating film 32, mention is made, for example, of a polyaryl ether (PAE) film. The organic insulating film is formed by depositing a precursor by spin coating and thermally curing at 350° C. to 450° C. Of course, the precursor is so prepared as to provide a porous film. Aside from the PAE film, there may be used a benzocyclobutene (BCB) film, a polyimide film and an amorphous carbon film.

Subsequently, a first mask forming layer 41, a second mask forming layer 42, a third mask forming layer 43, a fourth mask forming layer 44 and a fifth mask forming layer 45 are successively form on the second interlayer insulating film 32. The first mask forming layer 41 is formed, for example, of a 30 nm SiOC film, the second mask forming layer 42 formed, for example, of a 10 nm thick SiC film, the third mask forming layer 43 formed, for example, of a 100 nm thick SiO₂ film, the fourth mask forming layer 44 formed, for example, of a 50 nm thick SiN film, and the fifth mask forming layer 45 formed, for example, of a 50 nm thick SiO₂ film. Especially, the second mask forming layer 42 functions as a polishing stopper when an additional portion of a wiring material embedded in a subsequently formed wiring trench is polished, and is formed, for example, of a silicon carbide (SiC) insulating film, for which the thickness should ranges 3 nm to 20 nm. If the thickness of the second mask forming layer 42 is smaller than 3 nm, function as a polishing stopper cannot be expected. If the thickness exceeds 20 nm, a rise of dielectric constant that would negate the effect of using an organic insulating film of low dielectric constant as the second interlayer insulating film 32 is brought about. This is why it is preferred to form the second mask forming layer 42 within such a thickness range as indicated above. More preferably, the thickness ranges from 5 nm to 10 nm.

The first interlayer insulating film 31, second interlayer insulating film 32 and first mask forming layer 41 to fifth mask forming layer 45 are preferably formed of light transmitting materials, respectively. The formation with a light transmitting material allows easy optical alignment upon mask registration.

The SiN film of the fourth mask forming layer 44 is formed by use, for example, of a plasma CVD apparatus using, for example, monosilane (SiH₄) as a silicon source, ammonia (NH₃) as a nitriding agent, a dinitrogen monoxide (N₂O) gas as an oxidizing agent and an inert gas as a carrier gas.

Next, as shown in FIG. 3C, a resist film is formed on the fifth mask forming layer 45, and a second wiring trench pattern 62 is formed in the resist film according to an ordinary lithographic technique to form a resist mask 61.

Next, as shown in FIG. 3C, using the resist mask 61 (see FIG. 3B) as an etching mask, the fifth mask forming layer 45 is etched according to a dry etching method to form a fifth mask 55 having a second wiring trench pattern 56 formed by transfer of the second wiring trench pattern 62 (see FIG. 3B). When the SiO₂ film of the fifth mask forming layer 45 is etched by use of the resist mask 61, an ordinary magnetron etching apparatus is used. For this, octafluorocyclobutane (C₄F₈), carbon monoxide (CO) and argon (Ar) are used, for example, as an etching gas with gas flow ratios set at C₄F₈:CO:Ar=1:20:40, and a bias power is set at 1500 W and a substrate temperature set at 40° C. Under these etching conditions, an etching selection ratio (SiO₂/SiN) to the fourth mask forming layer 44 made of a SiN film can be obtained at about 4. Thus, the underlying fourth mask formed layer 44 is scarcely etched after etching of the fifth mask forming layer 45, the resist mask 61 and a residual deposit formed upon etching are completely removed by subjecting, for example, to ashing treatment based on an oxygen (O₂) plasma and a chemical treatment with an organic amine.

Next, a resist film is formed over the fourth mask forming layer 44 and the fifth mask 55 and subjected to an ordinary lithographic technique to form a connection hole pattern 64 in the resist film, thereby forming a resist mask 63. At the time, at least a part of the connection hole pattern 64 is superposed on the second wiring trench pattern 56 of the fifth mask 55 to form the resist mask 63.

For the formation of the resist mask 63, a step caused by the fifth mask 55 constituting the second wiring trench pattern 56 can be suppressed to 50 nm that generally corresponds to the fifth mask 55, so that there can be obtained a good connection hole resist pattern according to substantially the same lithographic characteristics as the case where a resist mask is formed at a flat portion. Moreover, where a bottom anti-reflective coating (BARC) is used in combination, a variation in embedded shape of the antireflective coating is minutely suppressed depending on the dimension of the second wiring trench pattern and the density of wirings. Thus, deterioration in resist shape at the time of exposure and a variation in focal depth causing a dimensional variation can be reduced.

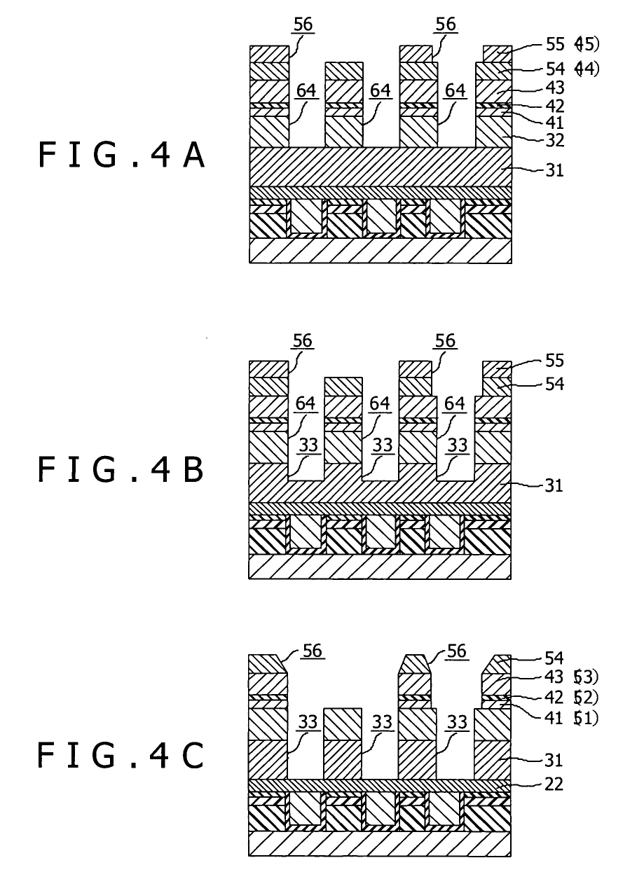

Subsequently, as shown in FIG. 4A, the fifth mask 55, fourth mask forming layer 44, third mask forming layer 43, second mask forming layer 42, first mask forming layer 41 and second inter layer insulating film 32 are, respectively, etched according to a dry etching method using the resist mask 63 having a connection hole pattern 64 (see FIG. 3C) as an etching mask, thereby forming the connection hole pattern as extended. During the course of the formation, the resist mask 63 is removed when the second interlayer insulating film 32 is etched. To this end, when the etching pattern 64 is formed in the interlayer insulating film 32, the remaining fourth mask forming layer 44 is used as the etching mask in the form of the fourth mask 54. At this etching stage, the first interlayer insulating film 32 is exposed at the bottom of the connection hole pattern 63. The second wiring trench pattern 56 is formed in the remaining fifth mask 55 through the above etching, and the etched fourth mask 54 has the connection hole pattern 64.

For opening the connection hole pattern 64 by etching the fifth mask (fifth mask forming layer 45) to the first mask forming layer 41, an ordinary magnetron etching apparatus is used, in which trifluoromethane (CHF₃), oxygen (O₂) and argon (Ar) are used as an etching gas, a gas flow ratio is set at CHF₃:O₂:Ar=5:1:50, and a bias power is set at 1000 W and a substrate temperature set at 40° C., for example.

In this embodiment, the etching selection ratio (SiO₂/SiN/SiO₂/SiC/SiOC) obtained under such etching conditions as indicated above is at approximately 1. The five layers of the fifth mask forming layer 45 to the first mask forming layer 41 are etched by one step thereby forming the connection hole pattern in an extended form. In this connection, however, where problems arise such as in resist selection ratio and conversion difference in etching, limitation is not placed on the manner of etching as set out above, but it is possible to effect two or more etching steps of successively etching the fifth mask forming layer 45, fourth mask forming layer 44, third mask forming layer 43, second mask forming layer 42 and first mask forming layer 41 and subsequently etching an intended mask forming layer selectively to an underlying mask forming layer or underlying insulating layer.

The opening of the connection hole pattern 64 at the interlayer insulating film 32 is carried out by use of an ordinary high density plasma etching apparatus using, for example, ammonia (NH₃) as an etching gas wherein an RF power is set at 150 W and the substrate temperature set at 20° C. Under these etching conditions, because the etching rate of the resist mask 63 is substantially equal to an etching rate of the second interlayer insulating film 32 made of an organic insulating film, the resist mask 63 is being etched during the curse of opening of the connection hole pattern 64 in the second interlayer insulating film 32. The fourth mask 44 made of a SiN film functions as an etching mask, so that a good opening shape of the connection hole pattern is ensured. For reference, the etching selection ratio to the SiO₂ film, SiN film, SiC film and SiOC film under etching conditions of the second interlayer insulating film 32 made of an organic insulating film is 100 or over.

Next, as shown in FIG. 4B, the fourth mask 54 is etched according to a dry etching method using the fifth etching mask 55 having the second wiring trench pattern 56 as an etching mask, thereby forming a fresh fourth mask 54 having the second wiring trench pattern 56. For the etching of the fourth mask 54 made of a SiN film, an ordinary magnetron etching apparatus is, for example, used. For instance, an etching gas used includes difluoromethane (CH₂F₂), tetrafluoromethane (CF₄), oxygen (O₂) and argon (Ar) with a gas flow ratio being at CH₂F₂ CF₄:O₂:Ar=2:1:2:20, and a bias power is set at 500 W and a substrate temperature set at 40° C.

Under the etching conditions as indicated above, an etching selection ratio (SiO₂/SiN) to the fifth mask 55 made of a SiO₂ film is at about 3. When the thickness of the fifth mask 55 is at about 55 nm, the wiring trench pattern 56 having an allowance sufficient for the thickness reduction of the fifth mask 55 can be made in the fourth mask 54 upon etching of the a 50 nm thick SiN film of the fourth mask 54. In the etching step of the fourth mask 54 made of SiN using the fifth mask 55 made of a SiO₂ film the first interlayer insulating film 31 that is exposed at the bottom of the connection hole pattern 64 and is made of the SiOC film is etched to part thereof, and the upper portion of the connection hole 33 is formed so that the connection hole pattern 64 is formed as extended. The etching selection ratio (SiN/SiOC) to the SiOC film under the above etching conditions can be made at less than 1. Accordingly, where the fourth mask 54 made of a 50 nm thick SiN film is etched, the connection hole 33 is dug into the first interlayer insulating film 31 to a depth, for example, of 25 nm to 95 nm.

Next, as shown in FIG. 4C, using the fourth mask 54 made of SiN as an etching mask, the lower layer of the first interlayer insulating film 31 is etched to cause the connection hole 33 to be formed and extended so that the barrier film 22 made of an underlying SiC film is exposed. At this stage, using the fourth mask 54 in which the second wiring trench pattern 56 has been formed, the third mask forming layer 43, second mask forming layer 42 and first mask forming layer 41 that are left in the wiring trench region are simultaneously removed to form the second wiring trench pattern 56 as extended. This etching is carried out using, for example, an ordinary magnetron etching apparatus wherein octafluorobutane (C₄F₈), carbon monoxide (CO), nitrogen (N₂) and argon (Ar) are used an etching gas with a gas flow ratio being at C₄H₈:CO:N₂:Ar=3:10:200:500, and a bias power is set at 1000 W and a substrate temperature set at 20° C., for example.

Under such etching conditions as indicated above, an etching selection ratio (SiO₂, SiC, SiOC/SiN) to the SiN film of 5 or over is obtained. For the etching of the first interlayer insulating film 31 that is left at the bottom of the connection hole 33 and is made of a 5 to 75 nm thick SiOC film, if the thickens of the fourth mask 54 made of SiN is 50 nm, a wiring trench pattern 46 of a good opening shape, which has an allowance sufficient for thickness reduction of the fourth mask 54 and is suppressed from upward extension or shoulder down of the wiring trench, can be formed as extended from the first mask forming layer 41 to the third mask forming layer 43. In this way, the third mask 53 made of the third mask forming layer 43 is formed, the second mask 52 made of the second mask forming layer 42 is formed, and the first mask 51 made of the first mask forming layer 41 is formed.

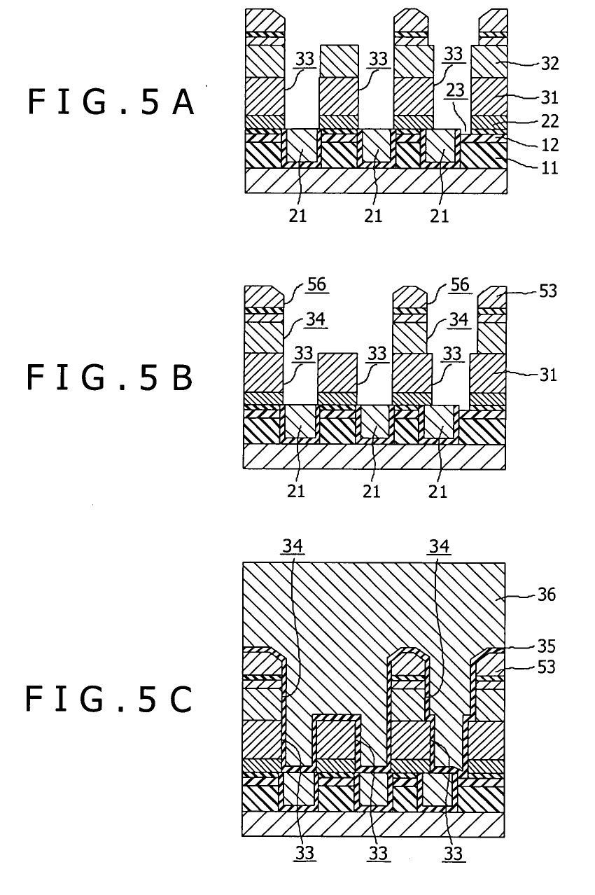

Next, as shown in FIG. 5A, the barrier film 2 made of a SiC film that exists at the bottom of the connection hole 33 is etched, with the result that the connection hole 33 arrives at the lower layer of the first wiring 21. In this connection, when registration deviation takes place between the connection hole 33 and the first wiring 21, a slit 23 occurs alongside of the first wiring 21. Although the etching selection ratio of the first interlayer insulating film 31 made of a SiOC film to the barrier film 22 made of a SiC film is, at most, at about 1, under which when the barrier layer at the bottom of the connection hole is subjected to overetching to a fully extent while taking into account a variation in etching amount, the thickness of the second insulating film 12 made of a SiOC film is so set as not to permit the first insulating film 11 made of an organic insulating film to be exposed. Thus, the slit 23 is not enlarged upon etching, in a subsequent step, of the second interlayer insulating film 32 made of an organic insulating film.

For the etching of the barrier film 22 at the bottom of the connection hole 33, an ordinary magnetron etching apparatus is used, for example, in which difluoromethane (CH₂F₂), oxygen (O₂) and Ar (argon) are used as an etching gas with a gas flow ratio being at CH₂F₂:O₂:Ar=2:1:5 and a bias power is set at 100 W, for example. It will be noted that the fourth mask 54 that is left on the third mask 53 made of a SiO₂ film and is made of a SiN film (see FIG. 5A) is removed in the course of etching of the barrier film 22 at the bottom of the connection hole 33.

Next, as shown in FIG. 5B, the second interlayer insulating film 32 is etched using the etching mask of the third mask 53 in which the wiring trench pattern 56 has been formed, thereby causing the second wiring trench 34 to be opened. In this manner, a given dual damascene process capable of communicating the connection hole 33 with the first wiring 21 is completed.

The etching of the second interlayer insulating film 32 for opening the second wiring trench is feasible by use of an ordinary high density plasma etching apparatus. To this end, ammonia (NH₃) is used an etching gas, and an RF power is set at 150 W and a substrate temperature set at 10° C. Under these etching conditions, the etching selection ratio to the first interlayer insulating film made of a SiOCN film is not lower than 100, so that processing of the wiring trench can be carried out without involving a variation in depth under good control.

Subsequently, an etched deposit left on side walls of the second wiring trench 34 and the connection hole 33 is removed by after-treatment using a chemical solution and an RF sputtering treatment and, after conversion of a copper degenerated layer into an ordinary copper layer at the bottom of the connection hole 33, a barrier layer 35 is formed on the third mask 53 so as to cover the inner surfaces of the second wiring trench 34 and the connection hole 33. This barrier layer 35 is usually a so-called barrier metal and is formed, for example, of a tantalum (Ta) layer. A copper seed layer (not shown) is further formed on the barrier layer 35. The barrier layer 35 and the copper seed layer (not shown) are, respectively, formed, for example, by a sputtering method. Thereafter, a wiring material film 36 is formed as being buried in the second wiring trench 35 and the connection hole 33. This wiring material film 36 is formed, for example, of copper or a copper alloy, and film formation is carried out by an electroplating or sputtering method.

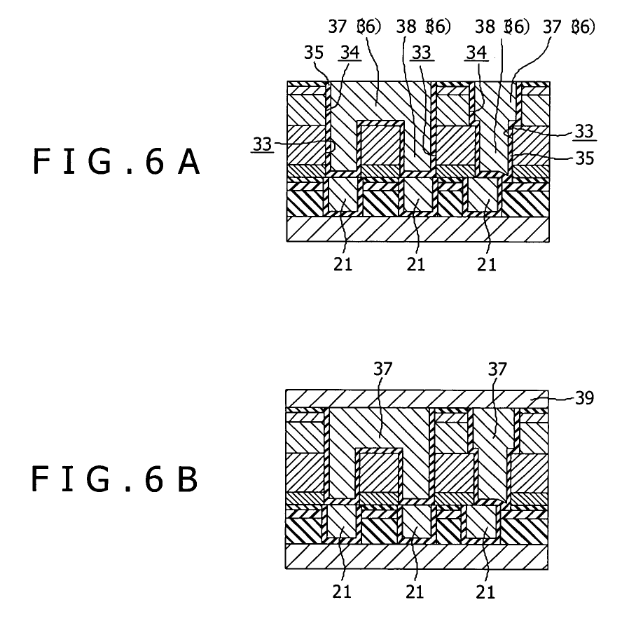

Next, the barrier layer 35 and the wiring material film 36 deposited over the third mask 53 are removed along with the third mask 53 according to a chemical mechanical polishing (CMP) method. As a result, as shown in FIG. 6A, a second-layered second wiring trench 37 made of a wiring material film 36 is formed, through the barrier layer 35, inside the second wiring trench 34 formed in the second interlayer insulating film 32. A plug 38 made of a wiring material film 36 is formed through the barrier layer 35 inside the connection hole 33 connected to the bottom of the second wiring 37. In this way, the second wiring 37 connected to the first wiring 21 by means of the plug 38 is formed.

One instance of chemical mechanical polishing (CMP) conditions for the wiring material film (copper film) 36 are such that a laminated pad of hard and soft foamed polyurethanes is used as a polishing pad, an alkaline silica-based polishing solution containing an oxidizing agent and a surface active agent is provided as a polishing liquid, an amount of the polishing solution is set within a range of 100 ml/minute to 500 ml/minute, for example, at 200 ml/minute, the number of revolutions of the polishing pad is at 100 rpm, the number of revolutions of a wafer is set at 110 rpm, a polishing pressure is set at 300 g/cm², and the polishing time is determined to allow over-polishing by 10% after removal of the copper from whole surfaces. Likewise, an instance of chemical mechanical polishing (CMP) conditions for the barrier layer (tantalum film) 35 is such that a laminated pad of soft and hard foamed polyurethanes is used as a polishing pad, an alkaline silica-based polishing solution containing an oxidizing agent and a surface active agent is provided as a polishing liquid, an amount of the polishing solution is set within a range of 100 ml/minute to 500 ml/minute, for example, at 200 ml/minute, the number of revolutions of the polishing pad is at 100 rpm, the number of revolutions of a wafer is set at 110 rpm, a polishing pressure is set at 300 g/cm², and the polishing time is set at 60 seconds.

For the CMP treatment, the conditions are so controlled that the selection ratio (SiO₂/SiC) between the third mask 53 made of a SiO₂ film and the second mask 52 made of a SiC film ranges about 10 to 100. Accordingly, irrespective of the wiring density and the wafer inplane, a variation in number of remaining films of the first mask 51 and the second mask 52 is suppressed to a low level.

In this embodiment, a final thickness of the second wiring 37 is controlled to be, for example, at about 120 nm. As shown in FIG. 6B, a barrier film 39 made, for example, of a SiC film is formed on the second wiring 37 as an antioxidant layer for copper, like the first wiring 21.

In the manufacturing method of a semiconductor device, a cap film of the second interlayer insulating film 32 has a stacked structure of the first mask 51 made of a SiOC film and the second mask 52 made of a SiC film. This film is able to reduce the interwiring capacitance over a cap made of a SiO₂ single film. The second mask 52 made of a SiC film acts as a stopper layer at the time of CMP, enabling a variation in thickness to be suppressed. Thus, where registration deviation occurs between the connection hole 33 and the first wiring 21, the third insulating film 13 which becomes a cap film of the first wiring 21 is not passed through, so that the first insulating film 11 made of an organic insulating film in which the first wiring 21 is formed is prevented from being damaged.

In forming a resist mask 63 having a connection hole pattern 64, the thickness of the fifth mask 55 wherein a step of an underlying layer is left is suppressed to be at about 50 nm, so that the resist mask 63 having the connection hole pattern 64 of high precision can be formed. The use of the resist mask 63 having the highly precise connection hole pattern 64 enables the connection hole 33 of a fine dimension to be stably opened without inviting shape deterioration. In this manner, good characteristics of contact between the first wiring 21 and the second wiring 37 are obtainable. The application of this embodiment ensures the manufacture of a semiconductive device having a dual damascene structure of a good wiring shape within an interlayer insulating film of low dielectric constant in high yield.

While a preferred embodiment of the present invention has been described using specific terms, such description is for illustrative purposes only, and it is to be understood that changes and variations may be made without departing from the spirit or scope of the following claims.

What is claimed is:

1. A semiconductor device comprising a first insulating film, a second insulating film, and a third insulating film that are successively stacked, and a wiring formed in a wiring trench formed in the stacked insulating films, wherein
said first insulating film is made of a film that has the lowest dielectric constant among the stacked insulating films,
said third insulating film serves as a polishing stopper, and
said second insulating film serves as an etching stopper.

2. The semiconductor device according to claim 1, wherein said third insulating film has a thickness of from 3 nm to 20 nm.

3. The semiconductor device according to claim 1, wherein said third insulating film is made of a material ensuring an appropriate polishing selection ratio relative to polishing of silicon oxide.

4. The semiconductor device according to claim 3, wherein said third insulating film is made of a silicon carbide material.

5. The semiconductor device according to claim 1, wherein said second insulating film is made of a material that ensures an appropriate etching selection ratio relative to etching of said third insulating film and is lower in dielectric constant than said third insulating film.

6. A method for manufacturing a semiconductor device comprising a stacking of a first insulating film, a second insulating film, and a third insulating film, and forming a wiring in a wiring trench formed in the stacked insulating films, wherein
said first insulating film is formed of a film that has the lowest dielectric constant among the stacked insulating films,
said third insulating film serves as a polishing stopper when said wiring is formed, and
said second insulating film serves as an etching stopper when a connection hole for communication to said wiring is formed.

7. The method according to claim 6, wherein said third insulating film has a thickness of from 3 nm to 20 nm.

8. The method according to claim 6 wherein said third insulating film is made of a material capable of taking a high polishing selection ratio relative to polishing of silicon oxide.

9. The method according to claim 8, wherein said third insulating film is made of a silicon carbide material.

10. The method according to claim 6, wherein said second insulating film is made of a material that ensures an appropriate etching selection ratio relative to etching of said third insulating film and is lower in dielectric constant than said third insulating film.

11. A method for manufacturing a semiconductor device provided with interlayer insulating films including an organic insulating film, the method comprising the steps of:
successively forming, on a substrate, a first insulating film that serves as a interlayer insulating film for a first wiring and is made of an organic insulating material, a second insulating film made of a SiOC material, a third insulating film made of a SiC material, and a fourth insulating film made of a SiO₂ material;
forming a resist mask having a first wiring trench pattern on the fourth insulating film; and
etching said fourth insulating film, said third insulating film, said second insulating film and said first insulating film through said resist mask used as an etching mask.

12. A method for manufacturing a semiconductor device provided with interlayer insulating films including an organic insulating film, the method comprising the steps of:
successively forming, on a substrate, a first insulating film that is an insulating film through which a connection hole is passed and is made of a SiOC material, and a second insulating film that is an insulating film in which a wiring is formed and is made of an organic insulating material;
successively forming, on said second insulating film, a first mask forming layer made of a SiOC material, a second mask forming layer made of a SiC material different in type from said first mask forming layer, a third mask forming layer made of a SiO₂ material different in type from said second mask forming layer, a fourth mask forming layer made of a SiN material different in type from said third mask forming layer, and a fifth mask forming layer made of a SiO₂ material different in type from said fourth mask forming layer;
patterning said fifth mask forming layer to form a wiring trench pattern;
forming a resist mask having a connection hole pattern on said fourth mask forming layer including a surface of said fifth mask;
etching, through an etching mask of said resist mask, said fifth mask forming layer to said first mask forming layer and said second insulating film to open a connection hole;
etching said fourth mask forming layer through an etching mask of said fifth mask to form a fourth mask having a wiring trench pattern and etching said first insulating film to part thereof to form the connection hole as extended;
etching said third mask to said first mask forming layer through an etching mask of said fourth mask to form a third mask, a second mask, and a first mask each having a wiring trench pattern, and etching said first insulating film left at a bottom of said connection hole to open a connection hole arriving at said substrate;
etching said second insulating film through an etching mask of said third mask to form a wiring trench in said second insulating film; and
removing said third mask left after the formation of said wiring trench.
